(19) United States
(12) Patent Application Publication
(10) Pub. No.: US 2023/0107258 A1
(43) Pub. Date: Apr. 6, 2023

(54) Structures for Three-Dimensional CMOS Integrated Circuit Formation

(71) Applicant: Sang-Yun Lee, Hillsboro, OR (US)

(72) Inventor: Sang-Yun Lee, Hillsboro, OR (US)

(73) Assignee: BeSang, Inc., Hillsboro, OR (US)

(21) Appl. No.: 17/491,856

(22) Filed: Oct. 1, 2021

(51) Int. Cl. H01L 27/092; H01L 27/06; H01L 23/522; H01L 29/423; H01L 29/78

(52) U.S. Cl. CPC H01L 27/0922; H01L 27/0688; H01L 23/5226; H01L 29/42356; H01L 29/7827

(57) ABSTRACT

Disclosed are novel structures and methods for 3D CMOS integrated circuits built with vertical transistors. A gate extension is selectively patterned by first patterning a sacrificial dielectric disposed on a gate material. A 3D CMOS IC comprises vertical transistors of one type constructed in one level and those of an opposite type in another level. The gate of lower-level vertical transistors may be coupled to a top interconnect directly through a 3D gate contact or indirectly through an upper-level via and a lower-level contact. A common-gate coupling may be formed between vertical transistors in different levels through a strapping contact or a gate via. A common-drain coupling may be formed between vertical transistors in different levels by forming upper-level vertical transistor on a piece of conductive film disposed over lower-level vertical transistor with or without an intervening top contact for lower-level vertical transistor.

### TECHNICAL FIELD

The present disclosure relates generally to the technical field of semiconductor integrated circuit devices.

### BACKGROUND

The desire to integrate a very high density memory into a chip in a given technology node has driven the adoption of three-dimensional (3D) structures. Vertical transistors utilizing semiconductor pillars formed over circuits of conventional planar transistors have proven to be suitable for addressing such need. However, the practice that vertical transistors are used nearly (if not entirely) exclusively for memory cells has given a notion that such transistors are suitable only for memory cells, but not for sense amplifiers and logic circuits.

With the advent of the state-of-the-art technology requiring extreme ultraviolet (EUV) lithography, however, the justification for vertical transistors is shifting to manufacturing cost of non-memory products as well as memory-intensive products. 3D structures based on vertical transistors in a less advanced (i.e. non-EUV) technology node are becoming a practical alternative to two-dimensional (2D) structures based on planar transistors in a more advanced (i.e. EUV-mandating) technology node, in terms of chip sizes and manufacturing costs with comparable performances, not only for high density memories but also for logic circuits.

A major hurdle against using vertical transistors for high-performance complementary metal-oxide-semiconductor (CMOS) integrated circuits (IC), which has been considered to be insurmountable, has arisen from the notion that vertical transistors have inherently low driving capability. This notion is due to semiconductor layers used for the construction of vertical transistors: polycrystalline or amorphous semiconductors resulting in a low carrier mobility and high leakages in transistors built from them. The polycrystalline or amorphous nature arises from the deposition of semiconductor layer on a dielectric layer, with no adequate room to anneal for fear of damaging the underlying interconnects and worsening the function and performance of the underlying circuits.

Another hurdle against using vertical transistors in CMOS logic circuits has been the predominant practice of implementing only n-type vertical transistors. Only transistors of a single type are sufficient for DRAM and Flash products, which are the only type of products built in 3D. This practice has raised the concern that CMOS IC may be impractical, if not impossible, in 3D structures.

### SUMMARY

Structures and methods for 3D CMOS IC are disclosed. A 3D CMOS IC comprises vertical transistors constructed from a single-crystalline semiconductor layer disposed above a substrate which has circuits comprising planar transistors. Vertical transistors are distributed among at least two levels, each level being limited to only one type of vertical transistors. This is to dope the vertical transistors and activate the dopants before transferring a single-crystalline semiconductor over the substrate. The process of making vertical transistors from so prepared material can avoid subjecting the circuit-containing substrate to a temperature that would exceed the tolerance of interconnects completed before transferring the semiconductor.

A gate extension is provided to a vertical transistor requiring a coupling of its gate to other nodes. A gate-extension mask is patterned over a region that touches or encompasses the vertical transistor in question. A two-step etch of a sacrificial dielectric disposed on gate material is described. The sacrificial dielectric is etched, preferably partly, with the gate-extension mask at a first etch step. With the gate-extension mask stripped off, the sacrificial dielectric is blanket-etched in a second etch step. The sacrificial dielectric is partly removed from the region originally covered with the gate-extension mask but completely removed elsewhere. The so-patterned sacrificial dielectric acts as a mask for the anisotropic etching of the gate material which is then patterned into gates and gate extensions. A gate extension is formed at the foot of the gate in the region which was under the gate-extension mask. When a common-gate coupling is needed between vertical transistors in the same level, a gate extension may be patterned and shared between the vertical transistors. Or, a gate extension may be formed on the side of one vertical transistor away from other vertical transistors and the vertical transistors are placed closely such that their gates are merged.

The construction of 3D CMOS IC is conceptually illustrated with the use of one vertical transistor of one type and one vertical transistor of the opposite type, with each vertical transistor located in its own level. The sequence of steps for forming each type of vertical transistors as well as the basic structures of the vertical transistors may be identical, regardless of the types, except for the type of dopants. The terminals (i.e. source, drain, and gate) of a vertical transistor located in a lower level may be coupled to a top interconnect disposed on an upper level, either directly through a 3D contact or 3D via formed between the terminal and the top interconnect, or indirectly through an upper-level via formed between the top interconnect and a conductive line of the upper level in conjunction with a lower-level contact formed between the terminal and that conductive line of the upper level.

A 3D CMOS inverter and a 3D CMOS transmission gate are used to illustrate the coupling between the terminals of vertical transistors in different levels. A common-drain coupling may be made in a totem-like manner by disposing an upper-level conductive line on lower-level vertical transistor and by forming the upper-level vertical transistor on that upper-level conductive line. There may be an intervening top contact for the lower-level vertical transistor under that upper-level conductive line. A top contact for a vertical transistor is one patterned on the top diffusion region of the vertical transistor. This type of coupling may be used to make a cascode coupling between vertical transistors in different levels by reversing the roles of the top and bottom regions of either the upper- or lower-level vertical transistors. By reversing the roles of top and bottom regions of both upper- and lower-level vertical transistors, a common-source coupling may be made.

A common-gate coupling between vertical transistors in different levels may be made in various ways. A first option uses a strapping contact for upper-level vertical transistor and a gate contact for lower-level vertical transistor. The strapping contact straps the upper-level gate extension to an upper-level conductive line which is patterned on the lower-level gate contact. In a second option, a 3D strapping contact straps the upper-level gate extension and the lower-level gate extension without an intervening upper-level conductive line. A third option places a gate via between the upper- and lower-level gate extensions. The upper-level gate extension has a gate contact standing on it. A fourth option drills a 3D gate contact which is formed between a piece of top interconnect and the lower-level gate extension and passes through the upper-level gate extension.

When both common-drain and common-source couplings are needed between a pair of vertical transistors in different levels, one of them may be made in the above-described totem-like manner. The other common coupling may be made through a lower-level via, which is formed between the conductive lines of lower- and upper-level vertical transistors. An upper-level via between that conductive line of the upper-level vertical transistor and a piece of top interconnect extended over to the top diffusion region of the upper-level vertical transistor would complete that other common coupling.

A second option for making common-source and common-drain couplings between a pair of vertical transistors in different levels is to couple the two vertical transistors in a top-to-top and bottom-to-bottom fashion. The conductive line for the upper-level vertical transistor is patterned on a lower-level via which is patterned on the conductive line for the lower-level vertical transistor, and the top diffusion region of the upper-level vertical transistor is coupled to the top diffusion region of the lower-level vertical transistor through a piece of top interconnect patterned on the top contact of the upper-level vertical transistor and an upper-level via which is formed on a separate upper-level conductive line patterned on the lower-level vertical transistor with an optional top contact for the lower-level vertical transistor.

This Summary is provided to introduce a selection of concepts in a simplified form that are further described below in Detailed Description. This Summary is not intended to identify key or essential features of the claimed subject matter, nor is it intended to be used as an aid in determining the scope of the claimed subject matter. Furthermore, the structures and methods disclosed herein may be implemented in any means and/or combinations for achieving various aspects of the present disclosure. Other features will be apparent from the accompanying drawings and from the detailed description that follows. Accordingly, the specification and drawings are to be regarded in an illustrative rather than a restrictive sense.

### BRIEF DESCRIPTION OF THE DRAWINGS

Example embodiments are illustrated by way of example and not limitation in the figures of the accompanying drawings, in which like references indicate similar elements.

FIG. 1A is a 3D perspective of a structure 100 illustrating that a gate extension 112a and a gate contact 119 thereon are formed for a certain vertical transistor. Vertical transistors of different widths are also illustrated. Only a few select layers are shown here for the sake of simplicity.

FIG. 1B illustrates a top view of structure 100. One may consider that it approximately represents a layout view, except the circular or rounded rectangular shapes of certain elements are actually drawn as squares or rectangles. Cross-sectional views made along dashed line A-A′ are shown in FIGS. 1C-1F at different stages of a manufacturing process.

FIG. 1C illustrates a cross-sectional view of structure 100 at an early stage in the formation of gate extension. A gate-extension mask 116 is patterned on a sacrificial dielectric 115 over a vertical transistor of interest which is disposed and planarized after disposing a gate material 111.

FIG. 1D is the structure of FIG. 1C modified after sacrificial dielectric 115 is partly etched and gate-extension mask 116 is subsequently removed.

FIG. 1E is the structure of FIG. 1D modified after dielectric 115 is partly etched over the region originally covered by gate-extension mask 116 of FIG. 1C, and gate material 111 is patterned into gates 112 and gate extensions 112a. Dielectric 115 is completely removed outside gate-extension mask 116.

FIG. 1F is the structure of FIG. 1E modified after disposing and planarizing a dielectric layer 117, forming contacts 119 and 119b through dielectric 117, and forming interconnects 120 on the contacts.

FIG. 1G is a cross-sectional view of a structure 100G illustrating a formation of common-gate coupling between vertical transistors in the same level. A common gate extension is patterned, and a gate contact is patterned, between the vertical transistors.

FIG. 1H is a cross-sectional view of a structure 100H illustrating an alternative formation of common-gate coupling between vertical transistors in the same level. It utilizes the merging of gates between closely placed vertical transistors, with a gate contact patterned on the side of one of the vertical transistors.

FIG. 2A illustrates a structure 200A comprising a vertical transistor of one type in one level and a vertical transistor of an opposite type in another level with contacts and interconnects therefor. The gate extension in the lower level is coupled to a top interconnect 220c through a 3D gate contact 239.

FIG. 2B illustrates a structure 200B as an alternative to structure 200A, where a conductive film (which is patterned into intermediate interconnect 202a-c) is disposed directly on semiconductor pillar 104 without an intervening top contact (119b of FIG. 2A). Also illustrated is an alternative that replaces 3D gate contact 239 of FIG. 2A with a via 229 standing on an intermediate interconnect 202c patterned on gate contact 119.

FIG. 2C illustrates a structure 200C, in which the vertical transistors of FIG. 2A are coupled as an inverter. The common-gate coupling is made through a strapping gate contact 229c in the upper level and through a gate contact 119 in the lower level. The common-drain coupling is made by forming the upper-level vertical transistor on an intermediate interconnect 202a which is patterned over and coupled to the top diffusion region of the lower-level vertical transistor.

FIG. 2D illustrates a structure 200D, in which the vertical transistors of FIG. 2A are coupled as an inverter like FIG. 2C. The common-gate coupling is made through a 3D strapping gate contact 239d.

FIG. 2E illustrates a structure 200E, in which the vertical transistors of FIG. 2B are coupled as an inverter. The common-gate coupling is made through an upper-level gate contact 219 and through a gate via 129.

FIG. 2F illustrates a structure 200F, in which the vertical transistors of FIG. 2B are coupled as an inverter like FIG. 2E. A 3D gate contact 239 makes the common-gate coupling by passing through the upper-level gate extension in order to reach the lower-level gate extension.

FIG. 2G illustrates a structure 200G, in which the vertical transistors of FIG. 2B are coupled as a transmission gate. One of common-drain or common-source couplings is made in the manner of FIGS. 2E-F, while the other coupling is made by an intermediate interconnect 202a shared between an upper-level via 229 and a lower-level via 129 and by a top interconnect 220b shorting upper-level via 229 to top contact 219b.

FIG. 2H illustrates a structure 200H, in which the vertical transistors of FIG. 2B are coupled as a transmission gate like FIG. 2G but in a top-to-top and bottom-to-bottom manner, by reversing the roles of top and bottom diffusion regions as source and drain of one of the vertical transistors.

The drawings referred to in this description should be understood as not being drawn to scale, except if specifically noted, in order to show more clearly the details of the present disclosure Like reference numbers in the drawings indicate like elements throughout the several views. Other features and advantages of the present disclosure will be apparent from accompanying drawings and from the detailed description that follows.

### DETAILED DESCRIPTION

Structures for 3D CMOS IC, together with the methods therefor, are disclosed. In the following description, for the purposes of explanation, numerous specific details are set forth in order to provide a thorough understanding of the various embodiments. However, it will be evident that one skilled in the art may practice various embodiments within the scope of this disclosure without these specific details.

The 3D nature of the present disclosure arises from the use of vertical transistors built above a substrate that typically contains circuits of planar transistors. “Vertical” or “planar” refers to whether one diffusion region (i.e. source or drain) of a transistor lies in a horizontal plane different from (e.g. above) or same as the other diffusion region.

We have previously disclosed structures and methods of constructing vertical transistors with single-crystalline semiconductors. Such vertical transistors are particularly attractive for high-performance 3D circuits because they offer an excellent performance which is comparable to, or may even exceed, that of conventional planar transistors. Excellence in performance of such vertical transistors comes mainly from reduced parasitic capacitance and high driving capability. Parasitic capacitance is low because vertical transistors made of semiconductor pillars have no source/drain-to-well junction. Driving capability is high as a result of high carrier mobility. Carrier mobility is high as a result of near-intrinsic doping of the single-crystalline channel, in a principle similar to fin-shaped field-effect transistors (referred to as FinFET in the art). A layer of single-crystalline semiconductor can be transferred from a donor wafer onto a circuit-containing substrate by a process of wafer bonding and cleaving.

A CMOS circuit comprises two opposite types of transistors: n-type and p-type. If both types of vertical transistors are built on a same plane (or level), transistors of different types are doped separately after disposing a layer of semiconductor prior to the disposition. Each type is implant-doped with masks for the source and drain regions as well the channel. Then, thermal activation of implanted dopants are required. The entire structure including circuits underlying the vertical transistors would be subjected to thermal activation. An activation temperature is usually higher than the limit that a metallic material such as copper can withstand. Furthermore, the underlying circuits may have their functions altered and their performance worsened during the thermal activation of the dopants. It is best, though not absolutely necessary, to avoid activation of dopants of the vertical transistors after disposing the semiconductor layer over the substrate. If one level of vertical transistors is confined to a single type, the vertical transistors can be doped prior to transferring the semiconductor layer from a donor wafer, and the activation of the dopants can be carried out independently of circuits built on a substrate (the receiving wafer). For this reason, we describe structures, and methods therefor, in which opposite types of vertical transistors are placed in separate levels.

In the present disclosure, gate extensions are used to facilitate the formation of gate contacts. We disclosed other structures and methods of forming gate contacts in application Ser. No. 17/083,026 “Structures of Gate Contact Formation for Vertical Transistors” and 17122219 “Methods of Gate Contact Formation for Vertical Transistors”, which are incorporated herein by reference. Such other structures and methods may be used to form gate contacts for vertical transistors in 3D logic circuits rather than being confined to memory arrays.

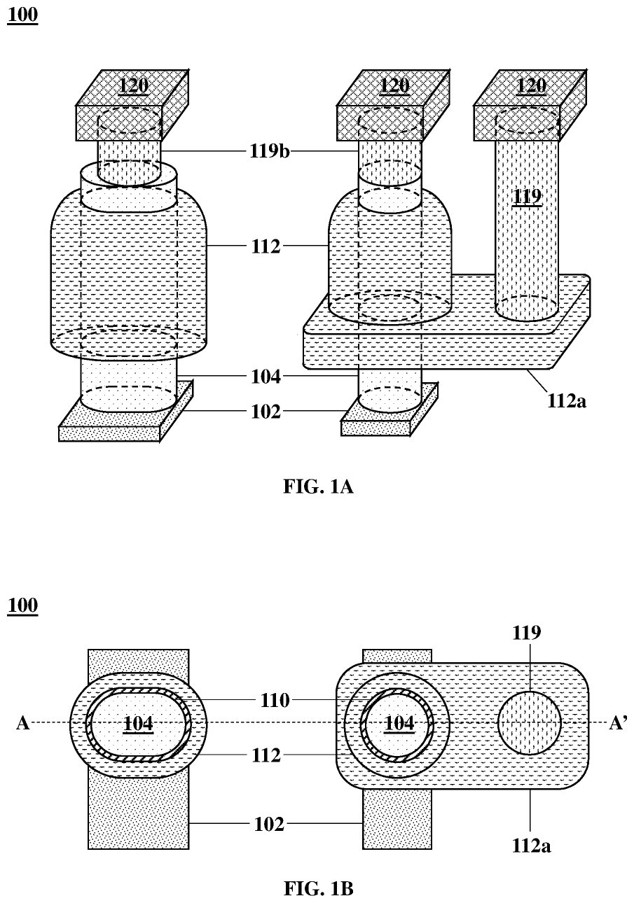

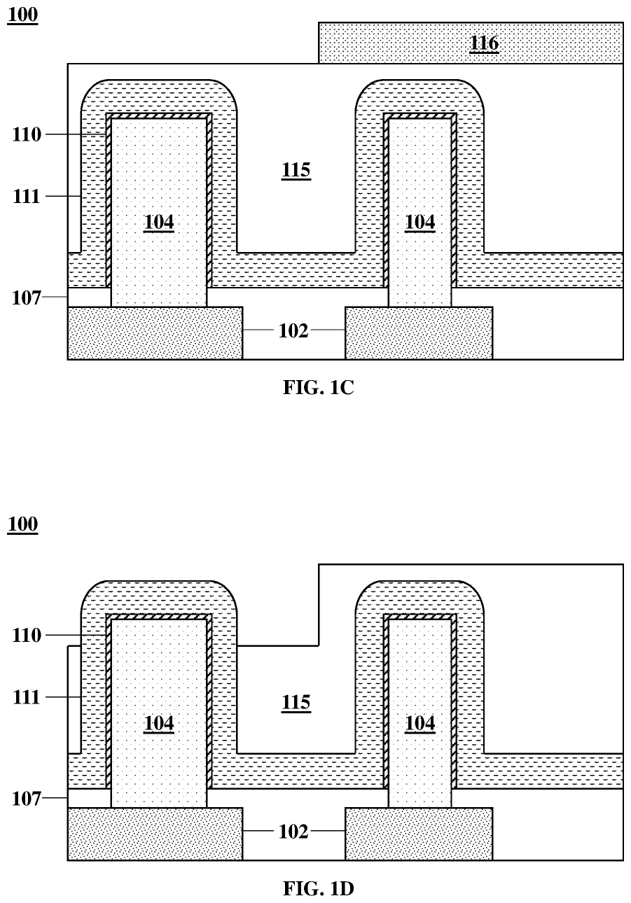

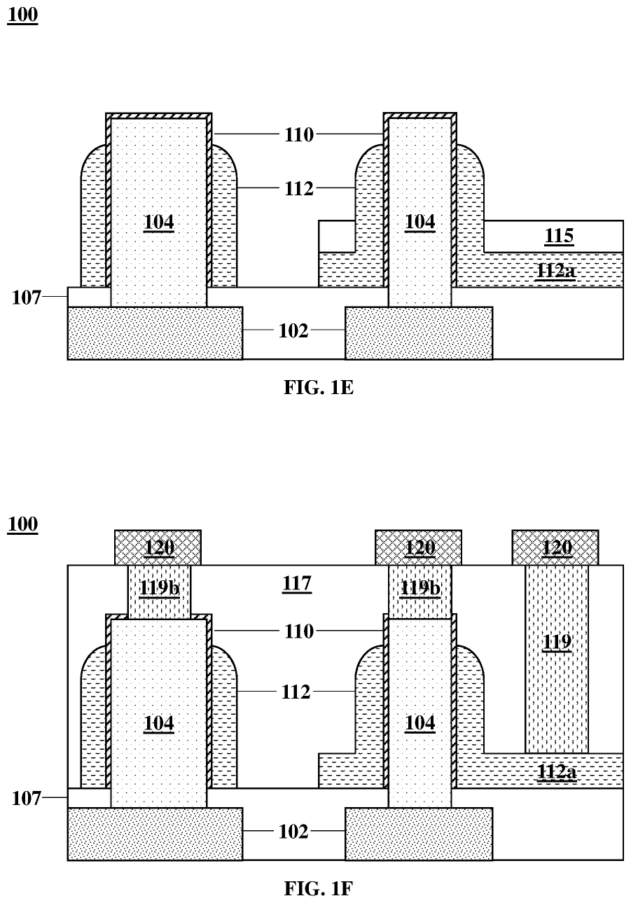

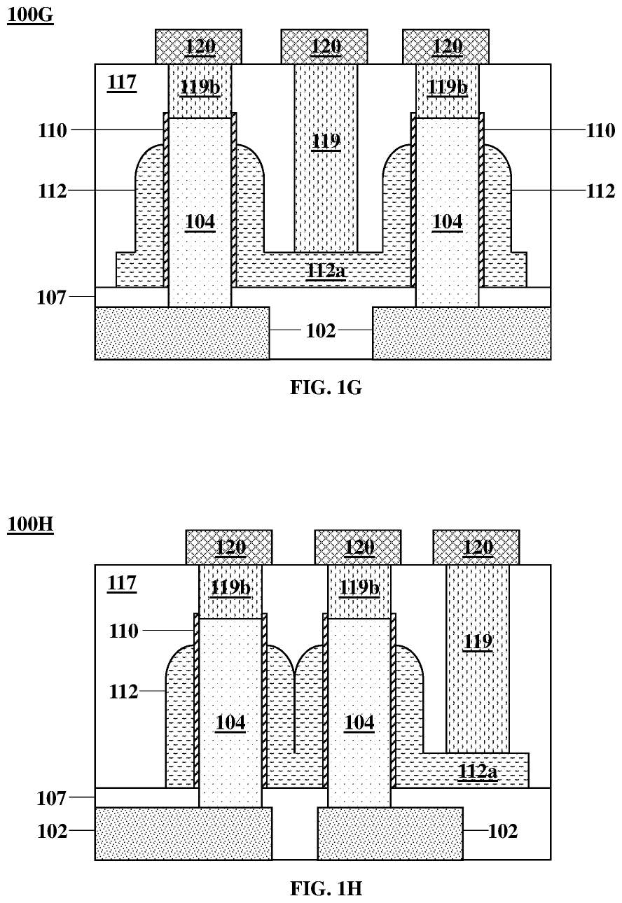

A gate extension is patterned for a vertical transistor requiring to have its gate coupled to other elements of the circuit. The gate extension makes a good landing pad for a gate contact. A gate-extension mask is introduced to pattern a gate extension. An exemplary structure and method are illustrated in FIGS. 1A-F. The particular set of illustrations is intended to consider a situation in which gates of some transistors are floated in a circuit that mainly comprises transistors whose gates are coupled to some other nodes or terminals. Semiconductor pillars of different widths are included in this first set of figures. The purpose is to show that transistors of different widths may be constructed simultaneously, but not as an example of providing a gate extension only to narrower transistors or of using wider transistors when the gate is floating.

Construction of vertical transistors starts with the disposition of a conductive film over a substrate on which various circuits comprising planar transistors may have been built. A layer of single-crystalline semiconductor is disposed on the conductive film. The semiconductor layer may be transferred from a donor wafer using a process comprising bonding and cleaving. The donor wafer may preferably be doped prior to the transfer of the semiconductor layer for the type of vertical transistors to be built within that layer. The semiconductor layer is patterned into tall semiconductor pillars standing on the conductive film. The conductive film is usually patterned into lines (often referred to as conductive lines in the present disclosure) during the formation of semiconductor pillars. Some lines of the conductive film may not have any semiconductor pillars standing on them. Since the semiconductor layer is disposed directly on the conductive film, semiconductor pillars are coupled to the respective lines of conductive film on which they stand.

FIG. 1A is a structure 100 in a 3D perspective after the patterning of an interconnect layer 120. Illustrated are vertical transistors of different widths, each comprising a semiconductor pillar 104 standing on a conductive film 102, a gate dielectric (not shown), and a spacer-like gate 112 surrounding a middle portion of the semiconductor pillar. The gate of one vertical transistor is coupled to the interconnect layer through a gate contact 119 standing on a gate extension 112a. Top contacts 119b (i.e. contacts on the top diffusion region of semiconductor pillars) couple the vertical transistors to the interconnect layer. When a vertical transistor is said to be coupled to an overlying interconnect, it means that the top diffusion region of the vertical transistor (or its semiconductor pillar) is coupled to the overlying interconnect. Dielectric layers filling the spaces between elements are not shown; they will be shown later in cross-sectional views.

FIG. 1B is a top view of structure 100, not including interconnect layer 120 and top contacts 119b of FIG. 1A. Geometries such as semiconductor pillars, gate extensions, and contacts take circular or rounded rectangular shapes, although drawn in a layout with square corners, due to effects of photolithography and etch on small geometries. The semiconductor pillars are usually defined by intersection of two masking steps, the first of which also defines the dimensions of conductive lines (i.e. lines of conductive film), and the second of which may clear the semiconductor layer on portions of the conductive lines where vertical transistors are not made. In a memory array comprising so made vertical transistors, the first mask is called a bit-line mask and the second a word-line mask. In this top view and subsequent cross-sectional views, gate dielectric 110 is shown disposed between the semiconductor pillars and the gate.

Illustrated in FIG. 1C is structure 100 at an early stage of a manufacturing process for selectively forming gate extensions for vertical transistors, starting with the formation of semiconductor pillars 104 standing on conductive lines 102. The cross-sectional view is taken vertically along the dashed line A-A′ of FIG. 1B. After the semiconductor pillars are formed, a dielectric film 107 is disposed on the conductive lines up to a certain bottom portion of the semiconductor pillars, filling the gaps between the conductive lines. A gate dielectric 110 and a gate material 111 are then disposed. The illustration indicates that the dielectric film serves to isolate the gate material from the conductive lines. A sacrificial dielectric 115 is disposed over the gate material. The sacrificial dielectric provides a planar surface over the otherwise high topography introduced by the tall semiconductor pillars. The topography would be too severe for any lithography without the sacrificial dielectric planarized above semiconductor pillars. The planar surface eases the patterning of a gate-extension mask 116. With gate-extension mask 116 so patterned, the sacrificial dielectric is etched, preferably partly, during a first etch step. Then the mask is stripped. One illustrated in FIG. 1D is the resulting structure. In the region outside the gate-extension mask, the gate material on the semiconductor pillars may protrude above the partly etched portion of the sacrificial dielectric, as in the illustration.

FIG. 1E illustrates the structure modified after performing a few steps on that of FIG. 1D. After removing gate-extension mask 116, sacrificial dielectric 115 is blanket-etched during a second etch step until hitting the top surface of gate material 111 between the semiconductor pillars outside the gate-extension mask. During the blanket etch, the sacrificial dielectric is partly etched under the region originally covered with the gate-extension mask. Thus, the pattern on the gate-extension mask is transferred to the sacrificial dielectric. During the second etch step, the top surface of the sacrificial dielectric under the now-gone gate-extension mask recedes sufficiently such that spacer-like gates for all vertical transistors can be formed during the subsequent anisotropic etch of the gate material. In the region that was originally covered with the gate-extension mask, the gate material on the semiconductor pillars protrudes above the sacrificial dielectric in a shape (but not necessarily a height or width) similar to the vertical transistor on the left portion of FIG. 1D.

Using so patterned sacrificial dielectric as a mask, the gate material is anisotropically etched to form gate 112. At the same time, a gate extension 112a is formed at the foot of the gate in the region where the sacrificial dielectric remains on the gate material. Further processing on the structure of FIG. 1E will lead to that of FIG. 1F. A dielectric layer 117 is disposed and planarized over the entire structure after the gate etch. The sacrificial dielectric remaining on the gate extension need not be removed before disposing dielectric layer 117. Gate contacts 119 and top contacts 119b are patterned through the dielectric layer. The contacts may be patterned simultaneously with one masking step, or separately with separate masks (i.e. gate contact mask and top contact mask). With the patterning of interconnect layer 120 on the contacts, the structure of FIG. 1F results.

Although the illustrations in FIGS. 1A-F suggests that the gate-extension mask should fully encompass a vertical transistor, the gate-extension mask may only partly touch, i.e. overlap with, the vertical transistor. So long as the gate-extension mask overlaps with the spacer-like portion of the gate, the gate extension remains continuous with the spacer-like gate. The piece of gate extension on the side opposite to that where a gate contact is formed is unnecessary, and will not exist if the gate-extension mask is not extended over to that opposite side.

In FIGS. 1G-H, structures and methods for common-gate coupling between vertical transistors in the same level (i.e. made from one semiconductor layer) are illustrated. A gate extension 112a and gate contact 119 may be patterned between the vertical transistors, as in FIG. 1G. Alternatively, the gate extension and the gate contact may be patterned for one vertical transistor with the other vertical transistors placed closely to that one vertical transistor, as in FIG. 1H. The alternative structure utilizes the merging of gates of vertical transistors placed in close proximity. Closely placed vertical transistors have their gates merged at the disposition of the gate material and remain merged after the anisotropic etch of the gate material, so long as the gate material is thick enough to fill the narrow space between closely placed vertical transistors.

For the sake of simplicity, in the construction of 3D CMOS IC, we will use one vertical transistor of one type and one vertical transistor of an opposite type to conceptually illustrate the construction of 3D CMOS IC. The type of vertical transistors refers to whether the vertical transistors are n- or p-type. The present disclosure illustrates only the structures that construct different types of vertical transistors in separate levels (i.e. using the separate semiconductor layers for them). However, both types of vertical transistors may be constructed in the same level. Some of the various structures and methods that we have previously disclosed for 3D CMOS sense amplifiers in application Ser. No. 17/122,173 “Three-Dimensional Memory with Three-Dimensional Sense Amplifiers” which is incorporated herein by reference may be used for 3D CMOS IC.

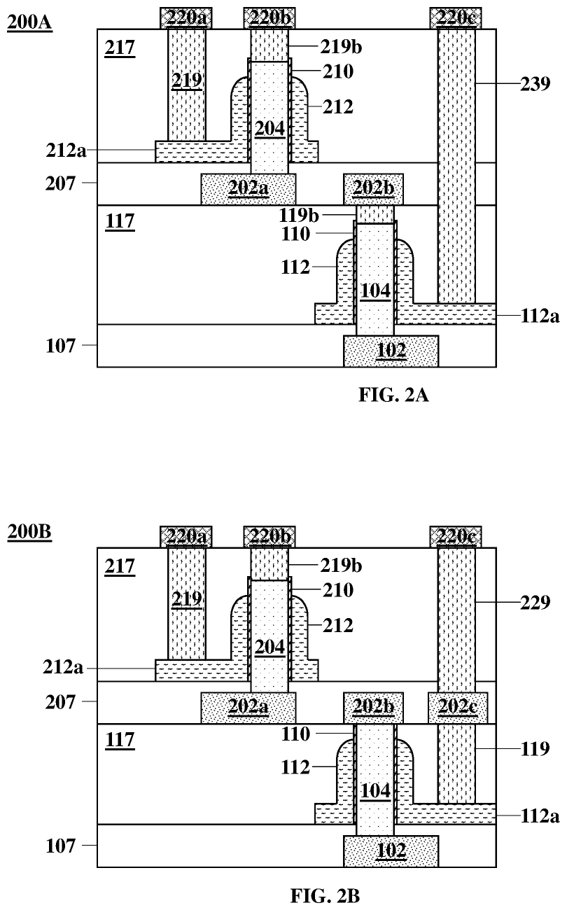

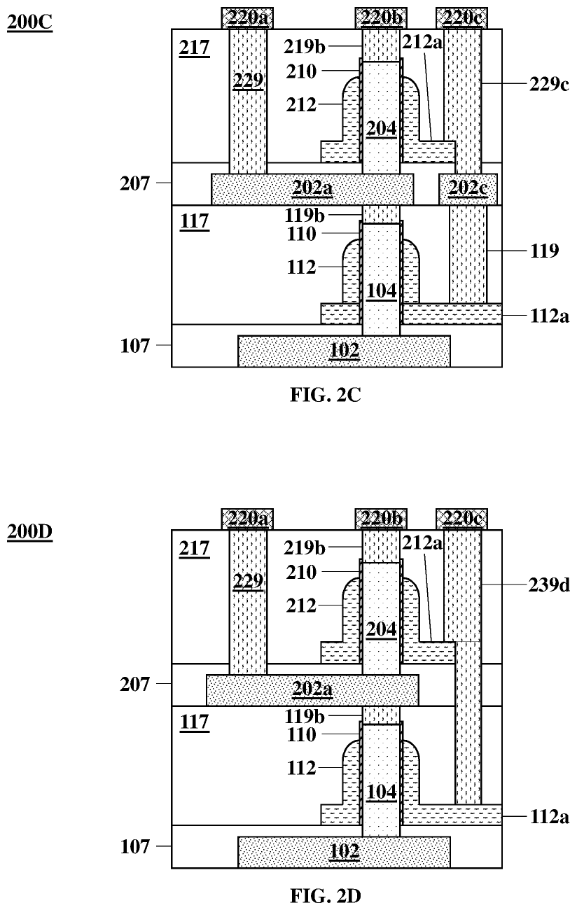

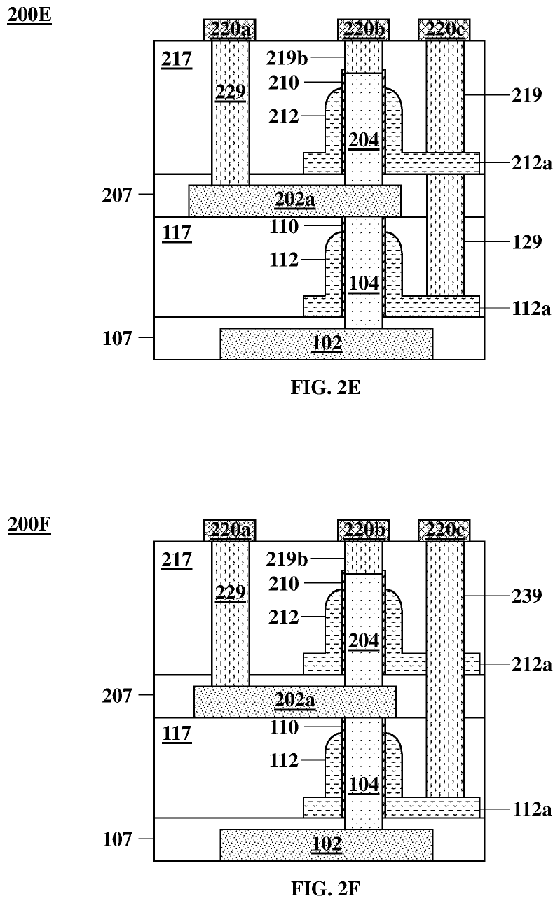

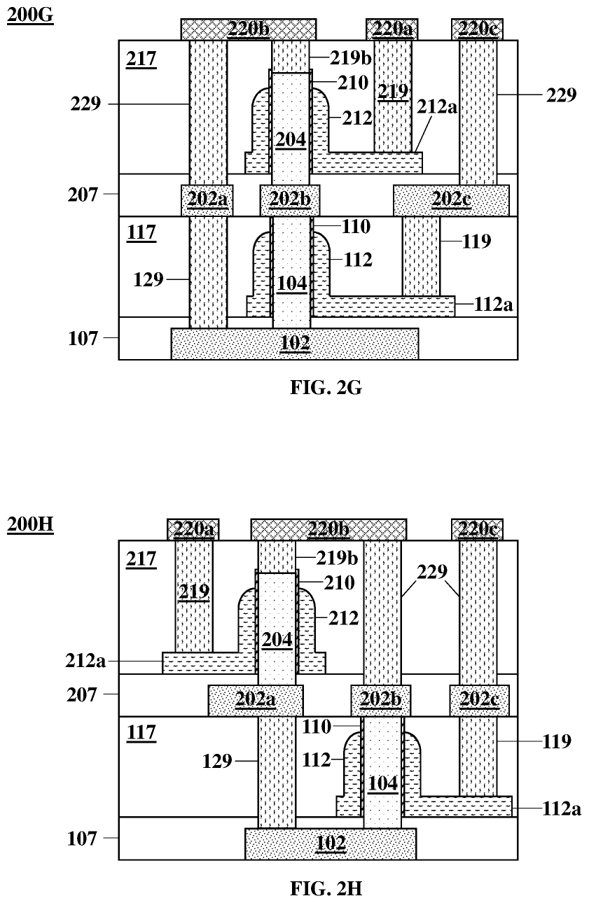

We will now describe construction of 3D CMOS IC comprising vertical transistors residing in different levels, in particular how the transistor terminals may be coupled to various nodes. FIGS. 2A-B illustrate how the vertical transistors residing in a lower level may be coupled to an interconnect layer disposed on an upper level. FIGS. 2C-F illustrate how a 3D CMOS inverter may be formed with two vertical transistors residing in different levels, mainly focusing on the formation of common-gate and common-drain couplings. FIGS. 2G-H illustrate how a 3D transmission gate may be formed with vertical transistors located in different levels, mainly focusing on the formation of common-drain and common-source couplings.

The two levels of vertical transistors as illustrated in the present disclosure may be formed by two identical sequences of steps except for the types of dopants. Each sequence involves wafer bonding and cleaving to transfer a single-crystalline semiconductor from a donor wafer. We described such a sequence in prior applications, e.g. application 17122219 “Methods of Gate Contact Formation for Vertical Transistors”.

FIG. 2A illustrates a structure 200A comprising a vertical transistor of one type (i.e. either n-type or p-type) in a lower level and a vertical transistor of an opposite type in an upper level. The types of vertical transistors are not specified in the illustrations of the present disclosure but should be understood as the same when in the same level but as different when in different levels. The lower-level vertical transistor comprises a semiconductor pillar 104 standing on a piece 102 of a conductive film, a gate dielectric 110, and a gate 112 with a gate extension 112a. The upper-level vertical transistor comprises likewise a semiconductor pillar 204 standing on a first piece 202a of a conductive film, a gate dielectric 210, and a gate 212 with a gate extension 212a. The upper-level gate is coupled to a first piece 220a of a top interconnect through an upper-level gate contact 219 formed on upper-level gate extension 212a. The lower-level gate is coupled to a third piece 220c of the top interconnect through a 3D gate contact 239 standing on lower-level gate extension 112a. Dielectric films 107 and 207 serve to isolate conductive lines from gates in the lower and upper levels, respectively. Dielectric layers 117 and 217 isolates transistors and contacts from each other within the respective levels.

The top diffusion region of the upper-level vertical transistor is coupled to a second piece 220b of the top interconnect through an upper-level top contact 219b. A top diffusion region refers to the region of a semiconductor pillar protruding above the gate. The top diffusion region of the lower-level vertical transistor is coupled through a lower-level top contact 119b to a second piece 202b of upper-level conductive film which may be coupled to a certain piece of the top interconnect through an upper-level via (not shown but similar to 229 of FIGS. 2B-H) whether located in the same plain of or a different plain than the cross section. The upper-level conductive film is sometimes referred to as intermediate interconnect in the present disclosure because it acts as interconnect lying between top interconnect and the lower-level conductive film.

FIG. 2B illustrates a structure 200B which is an alternative to structure 200A in terms of the manner of coupling the first gate to a piece of top interconnect. The lower-level gate is coupled to a third piece 202c of the upper-level conductive film through a lower-level gate contact 119 standing on the lower-level gate extension, and then to a third piece 220c of top interconnect through an upper-level via 229 formed on third piece 202c of the upper-level conductive film. The top diffusion region of the lower-level vertical transistor is coupled to a second piece 202b of the upper-level conductive film without a top contact. It may in turn be coupled to a certain piece of the top interconnect through a second upper-level via (not shown) formed at the same time as via 229.

The direct disposition of the upper-level conductive film on the lower-level semiconductor pillar may be used in structure 200A, or a top contact may be formed on the top diffusion region of the lower-level vertical transistor of structure 200B in a manner similar to that of structure 200A. Although the figures in the present disclosure include an upper-level top contact 219b for the coupling of the top diffusion region of the upper-level vertical transistor to a second piece 220b of top interconnect, such upper-level top contact may be omitted in a manner similar to the coupling of the top diffusion region of the lower-level vertical transistor to a piece of conductive film of the upper level.

A few structures for a 3D CMOS inverter are illustrated in FIGS. 2C-F. Like the circuit in FIGS. 2A-B, the 3D CMOS inverter comprises two vertical transistors residing in different levels. The common-drain coupling of an inverter may be accomplished in a totem-like manner, that is, by disposing a piece (202a of FIGS. 2C-F) of the conductive film for the upper-level vertical transistor on the top diffusion region of the lower-level transistor, with or without an intervening top contact (119b of FIGS. 2C-D) between that piece of upper-level conductive film and the top diffusion region of the lower-level vertical transistor. A piece of conductive film is said to be for or of a vertical transistor when that vertical transistor stands on that piece of conductive film. The top diffusion region of the lower-level vertical transistor and the bottom diffusion region of the upper-level vertical transistor are used as drains of the respective vertical transistors in the particular illustrations for an inverter.

When a common-source coupling but a separate-drain coupling between a pair of vertical transistors is needed, the roles of top and bottom diffusion regions (as source and drain) of both vertical transistors may be swapped, thanks to the symmetric nature of such transistors. By reversing the roles of top and bottom diffusion regions of either lower- or upper-level vertical transistor, one may form a cascode coupling between vertical transistors (such as the coupling between the source of a p-type transistor and the drain of an n-type transistor). It is unclear, however, whether such cascode couplings are needed or used in the art between transistors of different types.

The common-gate coupling of a 3D CMOS inverter may be formed in various ways. A first option is illustrated in FIG. 2C with a structure 200C. The gate of the lower-level transistor is coupled to a piece 202c of upper-level conductive film through a gate contact 119, and then to the gate of the upper-level transistor through a strapping gate contact 229c formed between that piece of upper-level conductive film and a piece 220c of top interconnect. A similar strapping contact (not shown), when necessary in some other types of circuits, may be formed to couple the gate and the bottom diffusion region (whether source or drain) of one vertical transistor.

FIG. 2D illustrates a structure 200D incorporating a 3D strapping gate contact 229d formed between the gate extension of the lower-level transistor and a piece 220c of top interconnect. This second option saves process steps of forming gate contact 119 of the first option but the contact resistance between the gates may be higher unless the 3D strapping gate contact is patterned wider at the top (thus occupying a larger area) to become as wide as the lower-level gate contact (119 of FIG. 2C) after passing by the upper-level gate extension.

A third option for common-gate coupling between vertical transistors located in different levels is illustrated in FIG. 2E with a structure 200E. It uses a gate via 129 formed between the gate extensions. The gates are then coupled to a top interconnect through an upper-level gate contact 219 standing on the upper-level gate extension. The gate via is formed after disposing upper-level dielectric film 207, and the upper-level gate extension is patterned on the gate via.

A fourth option is illustrated in FIG. 2F with a structure 200F. A 3D gate contact 239 is formed between a top interconnect and the lower-level gate extension. The 3D gate contact passes through and is coupled to the upper-level gate extension. The formation of such a 3D gate contact would involve at least 3 phases during an etch process: one selective endpoint etch for each of upper-level dielectric layer 217, upper-level gate extension 212a, and lower-level dielectric layer 117; or at least 2 phases: starting with a timed etch non-selective until after passing through the upper-level gate extension switching to an endpoint dielectric etch selective to lower-level gate extension. This option overcomes the shortcomings of the second option while preserving that option's advantages.

There are other methods possible for common-gate formation. An example would be to couple the lower-level gate to a piece of top interconnect as shown in FIGS. 2A-B and to pattern pieces 220a and 220c of top interconnect in FIGS. 2A-B as one larger piece. However, such methods would inevitably occupy a large area than those of FIGS. 2C-F. Although the illustrations in the present disclosure combines lower-level top contact 119b with the first two options (as in FIGS. 2C-D) but not with the latter two options (as in FIGS. 2E-F), different forms of coupling the top diffusion region of lower-level vertical transistor to an intermediate interconnect (i.e. a piece of upper-level conductive film) may be combined with any form of making common-gate coupling.

In FIGS. 2G-H, a transmission gate is used to illustrate a common-source coupling in addition to a common-drain coupling for a pair of vertical transistors in different levels. As illustrated with a structure 200G in FIG. 2G, a first option is to couple the bottom of the upper-level vertical transistor to the top of the lower-level vertical transistor, and the top of the upper-level vertical transistor to the bottom of the lower-level vertical transistor. One of the common couplings is made in the above-described totem-like manner, while the other of the common couplings may be made in different ways, such as by coupling piece 102 of conductive film for the lower-level vertical transistor to the same piece 220b of top interconnect that is coupled to the top diffusion region of the upper-level vertical transistor. The connection between piece 220b of top interconnect and piece 102 of lower-level conductive film can be made through a lower-level via 129 and an upper-level via 229. Or, a 3D via (not shown) like 3D gate contact 239 of FIG. 2A may be used between the top interconnect and the lower-level conductive film. In a manner similar to FIGS. 2C-D, the top diffusion region of the lower-level vertical transistor may have a top contact 119b to be connected to the piece 202b of upper-level conductive film on which the upper-level vertical transistor is formed.

In FIG. 2H, a structure 200H illustrates a second option of making common-source and common-drain couplings. The lower- and upper-level vertical transistors are coupled in a bottom-to-bottom and top-to-top manner, with neither of the common couplings made in the totem-like manner. The upper-level vertical transistor stands on piece 202a of its conductive film which is coupled through lower-level via 129 to piece 102 of the conductive film for the lower-level vertical transistor. The top diffusion region of the upper-level vertical transistor is coupled to the top diffusion region of the lower-level vertical transistor through piece 220b of top interconnect, upper-level via 229, and piece 202b of upper-level conductive film. As mentioned earlier, piece 202b of upper-level conductive film may be patterned on a lower-level top contact (such as 119b of FIGS. 2C-D) which in turn is patterned on the top diffusion regions of the lower-level vertical transistor.

Although the illustrations in FIGS. 2C-H appear to suggest vertical alignment of vertical transistors and vias in different levels whenever one upper-level element is coupled to one lower-level element, the two elements (whether a pair of vertical transistors, a pair of vias, or a vertical transistor and a via) in different levels need not be positioned on the same vertical line, so long as the pair share the same piece of upper-level conductive film. For example, the two vertical transistors with a common-drain (or common-source) coupling in FIGS. 2C-G need not be vertically aligned, so long as the upper-level vertical transistor is formed on the same piece of upper-level conductive film that is patterned to be coupled to the top diffusion region of the lower-level vertical transistor. Likewise, the upper-level via for coupling a lower-level vertical transistor to a top interconnect in FIG. 2H need not be vertically aligned with the lower-level vertical transistor so long as the upper-level via is patterned on the same piece of upper-level conductive film that is patterned to be coupled to the top diffusion region of the lower-level vertical transistor.

A coupling between the gate of a vertical transistor in one level and the top or bottom diffusion region of a vertical transistor in another level may be made in a manner similar to a common-gate, common-source, or common-drain coupling described so far. For example, a upper-level conductive line may be patterned on a lower-level gate contact with the upper-level vertical transistor formed on that piece of upper-level conductive film, in order to couple the lower-level vertical transistor's gate to the upper-level vertical transistor's bottom diffusion region. This would be equivalent to shorting pieces 202a and 202c of upper-level conductive film in FIG. 2B. A coupling between the top diffusion region of a lower-level vertical transistor and the gate of an upper-level vertical transistor may be made by patterning a upper-level conductive line on that top diffusion region and by coupling that upper-level conductive line and the upper-level gate extension to a common piece of top interconnect, whether through a strapping gate contact or through a via and a gate contact in the upper level. A coupling between the bottom diffusion region of a lower-level vertical transistor and the gate of an upper-level vertical transistor may be made by patterning an upper-level conductive line on a via formed on the conductive line for the lower-level vertical transistor and by coupling that upper-level conductive line and the upper-level gate extension to a common piece of top interconnect.

As illustrated in FIGS. 2G-H, the bottom diffusion region of the lower-level vertical transistor may be coupled to a piece of intermediate interconnect through a lower-level via (such as 129) formed between that piece of intermediate interconnect and the piece of lower-level conductive film on which the lower-level vertical transistor is formed. An upper-level via (such as 229) between that piece of intermediate interconnect and a piece of top interconnect may be used to complete the coupling between the bottom diffusion region of the lower-level vertical transistor and that piece of top interconnect.

The use of 3D CMOS inverter and 3D CMOS transmission gate in the present disclosure is to demonstrate the formation of gate-to-source-or-drain, common-gate, common-drain, common-source, and/or cascode coupling of vertical transistors of different types, rather than to limit the scope of the present disclosure to a circuit of two vertical transistors, an inverter, or a transmission gate. Other 3D CMOS circuits such as NOR, NAND, FIFO, comparator, or any custom circuit comprising vertical transistors can be constructed by various combinations of couplings for and between gates, sources, and drains of vertical transistors located in different levels, and therefore are deemed to lie within the scope of the present disclosure.

As used throughout the present disclosure, the word “may” is used in a permissive sense (i.e., meaning “having the potential to”), rather than a mandatory sense (i.e., meaning “must” or “required to”). Similarly, the words “include,” “including,” and “includes” mean “including, but not limited to” the listed item(s).

The foregoing descriptions of specific embodiments of the present disclosure have been presented for purposes of illustration and description. The embodiments were chosen and described in order to explain the principles of the invention and its practical application in the best way, and thereby enable others skilled in the art to best utilize the invention and various embodiments with various modifications as are suited to the particular use contemplated. They are not intended to be exhaustive or to limit the invention to the precise forms disclosed. Many modifications, variations, and rearrangements are possible in light of the above teaching without departing from the broader spirit and scope of the various embodiments. For example, they can be in different sequences than the exemplary ones described herein, e.g., in a different order. One or more additional new elements or steps may be inserted within the existing structures or methods or one or more elements or steps may be abbreviated or eliminated, according to a given application, so long as substantially equivalent results are obtained. Accordingly, structures and methods construed in accordance with the principle, spirit, and scope of the present invention may well be embraced as exemplarily described herein. It is intended that the scope of the invention be defined by the Claims appended hereto and their equivalents.

I/We claim:

1. A vertical transistor, comprising:
a semiconductor pillar standing on a conductive film;
a dielectric film disposed on said conductive film up to a bottom portion of said semiconductor pillar;
a gate dielectric disposed on said semiconductor pillar;
a gate disposed on said gate dielectric around a middle portion of said semiconductor pillar; and
a gate extension formed horizontally and contiguous with said gate at a bottom side of said gate.

2. The vertical transistor of claim 1, further comprising:
a gate contact formed on said gate extension.

3. A 3D CMOS IC, comprising:
a first vertical transistor of a first type in a first level, comprising a gate, a source region, and a drain region;
a second vertical transistor of a second type in a second level, comprising a gate, a source region, and a drain region;
a first gate extension formed horizontally and contiguous with said gate of said first vertical transistor at a bottom side of said gate of said first vertical transistor;
a second gate extension formed horizontally and contiguous with said gate of said second vertical transistor at a bottom side of said gate of said second vertical transistor;
a first voltage coupled to said source of said first vertical transistor; and
a second voltage coupled to said source of said second vertical transistor.

4. The 3D CMOS IC of claim 3, wherein:
said first vertical transistor and said second vertical transistor are of opposite types.

5. The 3D CMOS IC of claim 3, wherein:
said second level is above said first level.

6. The 3D CMOS IC of claim 5, further comprising:
a top interconnect disposed on said second level;
an intermediate interconnect disposed at a bottom of said second level;
a conductive film disposed at a bottom of said first level;
a first via formed in said first level;
a second via formed in said second level;
and wherein:
said top interconnect comprises a first piece patterned on said second via;
said intermediate interconnect comprises a first piece and a second piece;
said conductive film comprises a first piece;
said first piece of said top interconnect extends over and is coupled to said second vertical transistor;
said second via is patterned on said second piece of said intermediate interconnect;
said second vertical transistor is formed on said first piece of said intermediate interconnect;
said first piece of intermediate interconnect is patterned on said first via;
said first via is patterned on said first piece of said conductive film; and
said first vertical transistor is formed on said first piece of said conductive film.

7. The 3D CMOS IC of claim 5, further comprising:
an intermediate interconnect disposed at a bottom of said second level; wherein:
said intermediate interconnect comprises a first piece;
said first piece of said intermediate interconnect is patterned over and coupled to said first vertical transistor; and
said second vertical transistor is formed on said first piece of said intermediate interconnect.

8. The 3D CMOS IC of claim 7, further comprising:
a first via formed in said first level;
a second via formed in said second level;
a top interconnect disposed on said second level;
a conductive film disposed at a bottom of said first level;
and wherein:
said top interconnect comprises a first piece patterned on said second via;
said intermediate interconnect further comprises a second piece patterned on said first via;
said conductive film comprises a first piece;
said first piece of said top interconnect extends over and is coupled to said second vertical transistor;
said second via is patterned on said second piece of said intermediate interconnect;
said first via is patterned on said first piece of said conductive film; and
said first vertical transistor is formed on said first piece of said conductive film.

9. The 3D CMOS IC of claim 7, further comprising:
a 3D via formed through said first level and said second level;
a top interconnect disposed on said second level;
a conductive film disposed at a bottom of said first level;
and wherein:
said top interconnect comprises a first piece patterned on said 3D via;
said conductive film comprises a first piece;
said first piece of said top interconnect extends over and is coupled to said second vertical transistor;
said 3D via is patterned on said first piece of said conductive film; and
said first vertical transistor is formed on said first piece of said conductive film.

10. The 3D CMOS IC of claim 5, further comprising:
an intermediate interconnect disposed at a bottom of said second level; wherein:
said intermediate interconnect comprises a first piece and a second piece;
said first piece of said intermediate interconnect is disposed over and coupled to said first vertical transistor; and
said second vertical transistor is formed on said second piece of said intermediate interconnect.

11. The 3D CMOS IC of claim 10, further comprising:
a pillar contact formed between said first piece of said interconnect and a top surface of said first vertical transistor; wherein:
said first piece of said intermediate interconnect is coupled to said first vertical transistor through said pillar contact.

12. The 3D CMOS IC of claim 10, further comprising:
a via disposed on said first piece of said intermediate interconnect;
a top interconnect disposed on said second level;
and wherein:
said top interconnect is patterned on said via.

13. The 3D CMOS IC of claim 5, further comprising:
a first gate contact formed on said first gate extension;
a second gate contact formed on said second gate extension;
a first input coupled to said first gate extension through said first gate contact; and
a second input coupled to said second gate extension through said second gate contact.

14. The 3D CMOS IC of claim 13, further comprising:
a top interconnect disposed on said second level; wherein:
said first input is coupled to said top interconnect; and
said first gate contact extends fully between said top interconnect and said first gate extension.

15. The 3D CMOS IC of claim 13, further comprising:
an intermediate interconnect disposed at a bottom of said second level;
a via formed in said second level;
a top interconnect disposed on said second level;
and wherein:
said intermediate interconnect comprises a first piece and a second piece;
said top interconnect comprises a first piece and a second piece;
said first input is coupled to said first piece of said top interconnect;
said second input is coupled to said second piece of said top interconnect;
said first gate contact is formed between said first piece of said intermediate interconnect and said first gate extension;
said second vertical transistor is formed on said second piece of said intermediate interconnect;
said via is formed between said first piece of said intermediate interconnect and said first piece of said top interconnect; and
said second gate contact is formed between said second gate extension and said second piece of said top interconnect.

16. The 3D CMOS IC of claim 3, further comprising:
an input coupled to said gate of said first vertical transistor and to said gate of said second vertical transistor.

17. The 3D CMOS IC of claim 16, wherein:
said second level is above said first level.

18. The 3D CMOS IC of claim 17, further comprising:
a first gate contact formed on said first gate extension;
an intermediate interconnect disposed at a bottom of said second level;
a top interconnect disposed on said second level;
a second gate contact formed between said intermediate interconnect and said top interconnect;
and wherein:
said intermediate interconnect is patterned on said first gate contact;
said second gate contact is patterned as a strapping contact for said second gate extension and for said intermediate interconnect; and
said input is coupled to said top interconnect.

19. The 3D CMOS IC of claim 17, further comprising:
a top interconnect disposed on said second level;
a 3D gate contact formed between said top interconnect and said first gate extension;
and wherein:
said top interconnect is patterned on said 3D gate contact;
said 3D gate contact is patterned as a strapping contact for said second gate extension and for said first gate extension; and
said input is coupled to said top interconnect.

20. The 3D CMOS IC of claim 17, further comprising:
a gate via formed on said first gate extension;
a gate contact formed on said second gate extension;
a top interconnect disposed on said second level;
and wherein:
said second gate extension is patterned on said gate via;
said top interconnect is patterned on said gate contact; and
said input is coupled to said top interconnect.

21. The 3D CMOS IC of claim 17, further comprising:
a 3D gate contact formed on said first gate extension;
a top interconnect disposed on said second level;
and wherein:
said top interconnect is patterned on said 3D gate contact;
said 3D gate contact is patterned between said top interconnect and said first gate extension;
said 3D gate contact passes through said second gate extension; and
said input is coupled to said top interconnect.

22. The 3D CMOS IC of claim 3, further comprising:
an output coupled to said drain of said first vertical transistor and said drain of said second vertical transistor.

23. The 3D CMOS IC of claim 3, further comprising:
an intermediate interconnect disposed at a bottom of said second level; wherein:
said second level is above said first level;
said intermediate interconnect is patterned over and coupled to said first vertical transistor; and
said second vertical transistor is formed on said intermediate interconnect.
